(19) United States
(12) Patent Application Publication
(10) Pub. No.: US 2025/0322122 A1
(43) Pub. Date: Oct. 16, 2025

(54) SYSTEMS AND METHODS FOR OPTIMIZING THE CONVERSION OF FEEDSTOCK INTO RENEWABLE ENERGY

(71) Applicant: Vanguard Renewables Holdings, LLC, Weston, MA (US)

(72) Inventors: John Hanselman, Weston, MA (US); Rajkumar Sunchukeshava, Westborough, MA (US); Kaylyn Bacha, Allston, MA (US); Kimberly Walker, Danvers, MA (US)

(73) Assignee: Vanguard Renewables Holdings, LLC, Weston, MA (US)

(21) Appl. No.: 19/174,331

(22) Filed: Apr. 9, 2025

Related U.S. Application Data
(60) Provisional application No. 63/632,139, filed on Apr. 10, 2024.

(51) Int. Cl. G06F 30/27; B09B 3/60

(52) U.S. Cl. CPC G06F 30/27; B09B 3/60

(57) ABSTRACT

Provided are systems and methods configured to optimize processing of feedstock sources into renewable energy. Optimization over conventional approaches can begin with systematic functionality at the first steps of delivering feedstock to various digester locations. Optimizing transport of materials to the various locations can significantly impact production efficiency and resultant greenhouse gas emissions stemming from such processing. Various embodiments resolve the technical issues of building the most efficient system to account for greenhouse gas emissions as well optimization of renewable energy production from source material having varying quality, consistency, and location. Trained ML models can be used to predict efficient use of resources across groups of digesters, various feedstock streams, respective locations, and the resources required to bring the feedstock to the digesters. According to some examples, the models can predict the most efficient distribution, limiting resource usage and limiting greenhouse gas emissions as part optimizing renewable gas output.

### RELATED APPLICATIONS

This Application claims priority under 35 U.S.C. 119(e) to and is a Non-Provisional of U.S. Provisional Application Ser. No. 63/632,139, filed Apr. 10, 2024, entitled “SYSTEMS AND METHODS FOR OPTIMIZING THE CONVERSION OF FEEDSTOCK INTO RENEWABLE ENERGY.” The entirety of which application is incorporated herein by reference in its entirety.

### BACKGROUND

The conversion of biomass and other feedstocks into renewable fuels is an evolving industry. Not only does this technology provide renewable fuels but allows for the recycling of otherwise wasted resources. The goal of such industries is to reduce waste and improve re-use of resources in generating renewable energy.

### SUMMARY

The inventors have realized that there are a number of opportunities to improve the efficiency of various feedstock and digester systems. Conventional approaches utilize ad hoc analysis and provide limited options for optimizing feedstock processing. Many conventional implementations simply struggle to connect feedstock sources to digester systems. They often fail to reduce carbon emissions during production and suffer from inconsistent pipelines and do not fully utilize existing resources. According to some aspects, the ability to optimize processing can begin with developing systematic functionality from the very first steps of scheduling feedstock loads, understanding the chemistry associated with these loads and composites of materials present in the digester, and delivery of feedstock to various digester locations.

According to various embodiments, optimizing transport of materials to the various locations can significantly impact production efficiency and significantly impact greenhouse gas emissions in connection with such processing. Coupling approaches that produce renewable energy sources with options that minimize greenhouse gas emissions, even at the transportation level, provides improvement over many known approaches and implementation. In various embodiments, the technical issue of building the most efficient system includes accounting for greenhouse gas emissions and optimization of source material utilization, while resolving variability in quality and location of same.

In further embodiments, machine learning models can be trained to predict the most efficient use of resources across groups of digesters, various feedstock streams, respective locations, and the resources required to bring the feedstock to the digesters. According to some examples, the models can predict the most efficient distribution, limiting resource usage and limiting greenhouse gas emissions as part of optimizing distribution and renewable energy production.

According to another aspect, machine learning models can be trained on digester performance given various feedstock sources. Various embodiments of the machine learning models can be trained to predict digester performance given information on feedstock source availability as inputs. Further embodiments can include trained models that predict renewable gas output based on one or more of the following information inputs: availability by digested material, feedstock quality assessment (e.g., by digested material), and can also be trained on external factors that impact efficiency (e.g., temperature, season, weather, humidity, site location, etc.), among other options. In some embodiments, multiple models can be trained on respective information discussed in greater detail below (including, e.g., feedstock input (e.g., by digested material), feedstock input quality, external factors, etc.), and combined models can be used to predict an output efficiency of the digesters under current and/or predicted contexts or information.

Various embodiments can improve efficiencies in digester performance based on the model's predictions relative to known implementation. In still other embodiments, the models provide input targets that achieve improved efficiency in respective digesters, which can be used in distribution models that provide the optimized utilization of resource (including e.g., transportation, limit distances, fully utilize feedstock source, optimization of feedstock source utilization, minimize greenhouse gas emissions, etc.) for delivery of feedstock to match/meet the input targets. Other examples include allocations that achieve the optimal input levels with safety margins that provide for unanticipated shortages, or issues that are not identified/predicted by any model. In other examples, while models may not predict specific shortages (e.g., due to extreme events), various models can enable the system to increase and decrease safety margins to account for the likelihood of such event or a prediction on increased/decreased likelihood of disruption. In various embodiments, the interaction between the distribution models and the utilization models achieves new efficiencies and functions not available in many conventional implementations. The interaction also provides for dynamic, often real time, adjustments to resource utilization, and can even be tailored to adjust for weather conditions dynamically, accounting even for external events that cannot be predicted by models except in short duration circumstances (e.g., days, hours, etc.).

Still other aspects, examples, and advantages of these exemplary aspects and examples, are discussed in detail below. Moreover, it is to be understood that both the foregoing information and the following detailed description are merely illustrative examples of various aspects and examples and are intended to provide an overview or framework for understanding the nature and character of the claimed aspects and examples. Any example disclosed herein may be combined with any other example in any manner consistent with at least one of the objects, aims, and needs disclosed herein, and references to “an example,” “some examples,” “an alternate example,” “various examples,” “one example,” “at least one example,” “this and other examples” or the like are not necessarily mutually exclusive and are intended to indicate that a particular feature, structure, or characteristic described in connection with the example may be included in at least one example. The appearances of such terms herein are not necessarily all referring to the same example.

### BRIEF DESCRIPTION OF THE DRAWINGS

Various aspects of at least one embodiment are discussed herein with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description or any claim are followed by reference signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1 is a block diagram illustrating system elements and process flow, according to one embodiment;

FIG. 2A is a block diagram illustrating system elements and process flow, according to one embodiment;

FIG. 2B is a block diagram illustrating system elements and process flow, according to one embodiment;

FIG. 2C is a block diagram illustrating system elements and process flow, according to one embodiment;

FIG. 2D is a block diagram illustrating system elements and process flow, according to one embodiment;

FIG. 3 is an example process flow for dispatching material to processing sites, according to one embodiment; and

FIG. 4 is a block diagram of an example computer system improved by implementation of the functions, operations, and/or architectures described herein.

FIG. 5 is an example process flow, according to one embodiment;

FIG. 6 is an example process flow, according to one embodiment;

FIG. 7 is an example process flow, according to one embodiment;

FIG. 8 is an example process flow, according to one embodiment;

FIGS. 9A-B show an example process flow with example system elements, according to one embodiment;

FIGS. 10A-B show an example user interface, according to one embodiment;

FIG. 10C shows example drop down display displays associated with the user interface, according to one embodiment;

FIG. 11 is an example user interface, according to one embodiment;

FIG. 12 is an example user interface, according to one embodiment; and

FIG. 13 is an example user interface, according to one embodiment.

### DETAILED DESCRIPTION

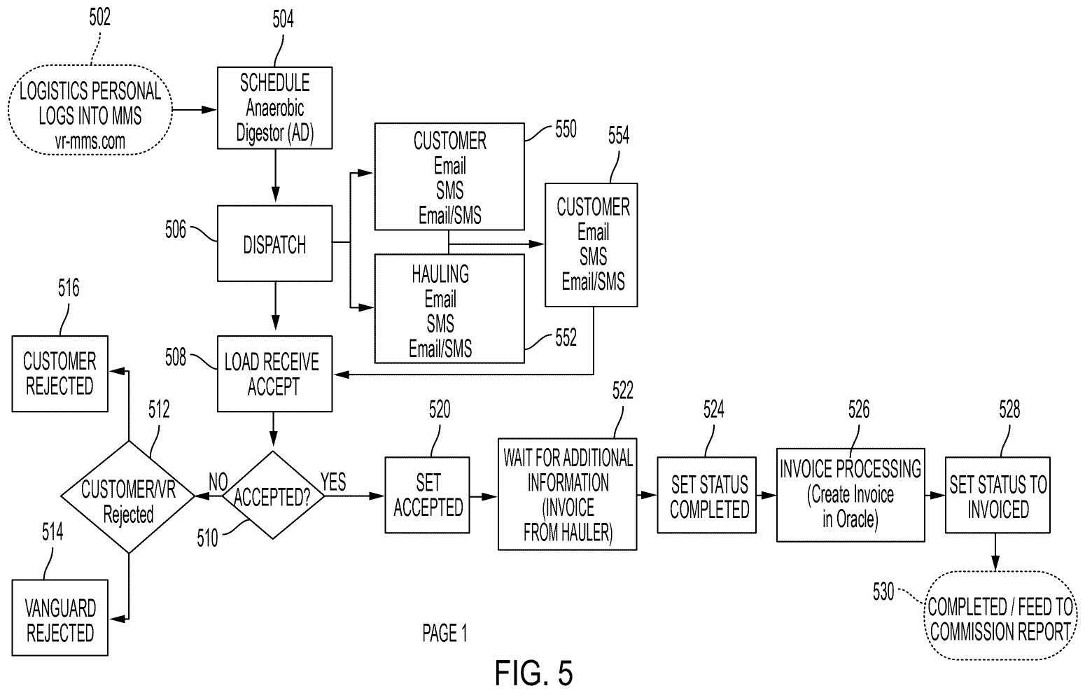

According to various embodiments, systems and methods for optimizing the conversion of feedstock into renewable energy incorporate artificial intelligent (“AI”) models to improve functionality and efficiency of the conversion. Some embodiments are configured to leverage the AI models to further optimize resource utilization during the various stages of converting feedstock into renewable energy, including transportation of feedstock source and optimization of biological processing into a renewable energy output. FIGS. 5-7 provide an overview of example scheduling pathways for managing feedstock distribution to digester systems. Each of the scheduling options can be leveraged and monitored by various embodiments of the system to define sets of training data for machine learning (“ML”) models.

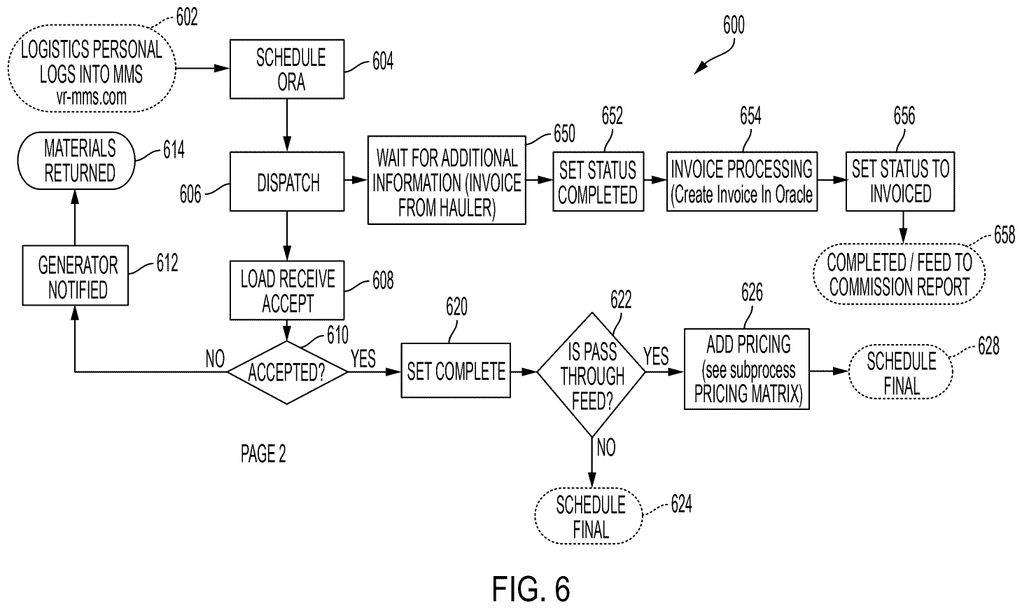

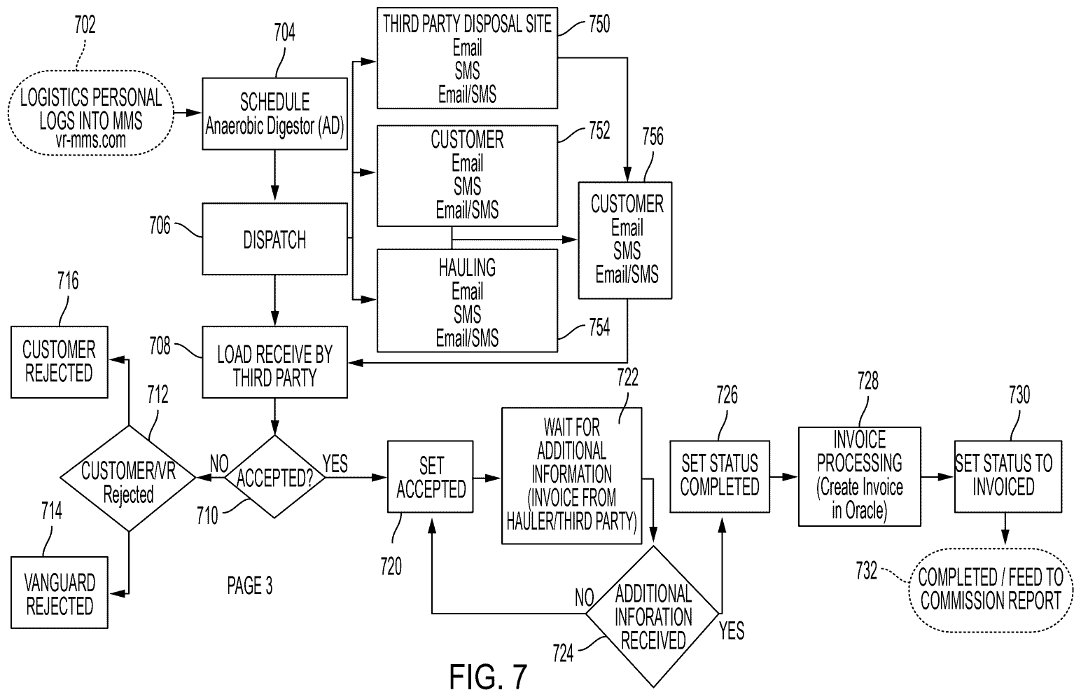

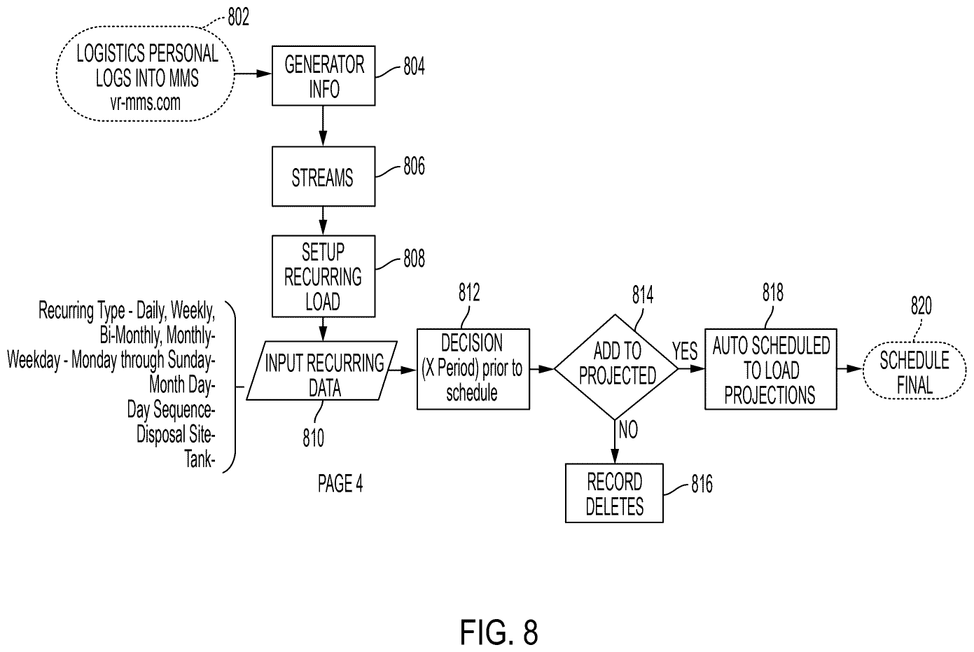

The machine learning models can be executed by the system to improve the scheduling and dispatch steps in the process flows illustrated (e.g., FIG. 5 “Schedule Anaerobic Digester,” “Dispatch”; FIG. 6 “Schedule ORA (“ Organics Receiving Area ”), “Dispatch”; and FIG. 7 “Schedule Anaerobic Digester,” FIG. 8 “Dispatch,” among other options and flows). In some embodiments, the machine learning models are used in conjunction with known feedstock loads (e.g., consistent and/or recurring delivery) to build optimized delivery schedules, for example, at “Decision,” when constructing a final schedule. In some embodiments, known or consistent deliveries are incorporated into projections of need and availability at “Auto Scheduled to Load Projection,” to enable the system to generate a final delivery schedule. Not shown on FIG. 8 are the options of re-evaluating projected loads and feedstock availability as the time for execution of the transport is approaching available in various embodiments.

In some embodiments, the combination of known deliveries with projection of availability and need can be dynamically adjusted up and until transit vehicles begin their routes. According to one example, this flexibility is unavailable in many conventional systems and improves over known approaches.

Examples of the methods, devices, and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements, and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element, or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

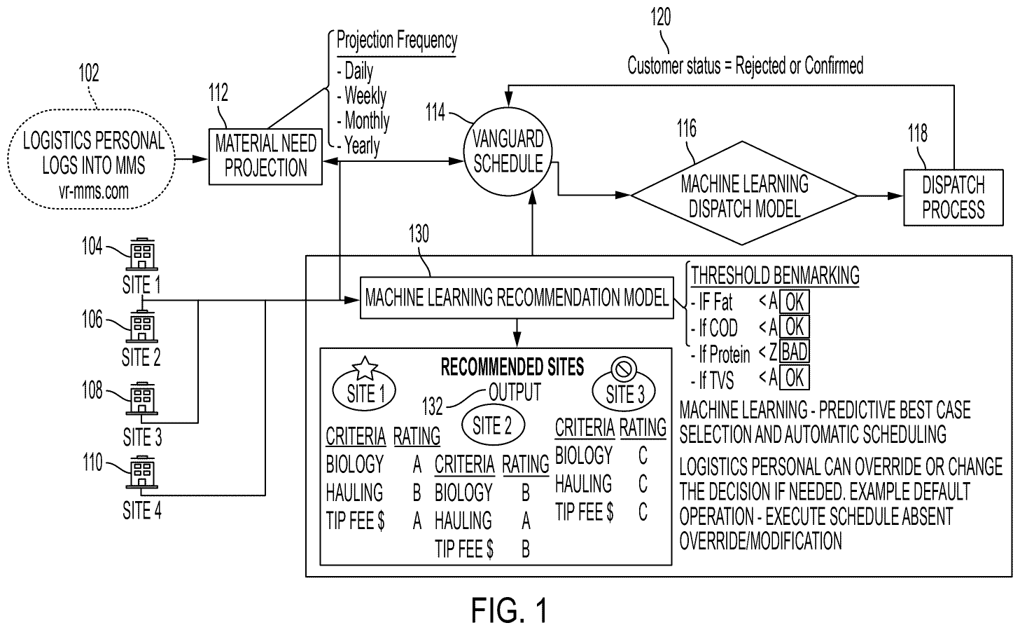

FIG. 1 is a block diagram 100 of example system components and process flow for predictive scheduling. The system and flow are configured to manage delivery and conversion of biomass into renewable energy sources (e.g., renewable gas). According to one embodiment, end users can access the system (e.g., at 102) to manage delivery and production of renewable energy at any number of processing sites (e.g., 104-110). The processing sites can be associated with one or more digesters configured to convert biomass or feedstock into, for example, renewable gas. According to one example, the system uses a projected material need (e.g., 112) to build an optimized schedule (e.g., 114) for meeting that projected need at cach respective site. According to some embodiments, the system executes a machine learning model (e.g., 116) for determining an optimized dispatching schedule including delivery routes from feedstock sources to the respective processing site locations. Once the optimized dispatching schedule is generated it can be automatically executed (e.g., 118).

In further embodiments, end users can modify a proposed delivery schedule or override the proposed schedule. In some examples, the system is configured to automatically construct a dispatching schedule based on predicted needs for the system and production, and further optimize the schedule against greenhouse gas emission produced as part of end-to-end operation. The scheduler can be presented to an administrator or authorized used via a user interface (“UI”), and the UI can be configured with selectable options to enable the user to visualize prediction data and/or actual measurement data. These detailed visualizations can be used to adjust feedstock sources, locations, source volume, as well as other aspects of dispatch and/or scheduling. The system can select and present optimized values to the user to enable them to confirm the optimized values or simply not override system generated values, as well as present options to refine. In some examples, adjustments can include a visualization of changes in a calculated optimization. One visualization can present greenhouse gas optimization values in conjunction with safety margin values so the user can adjust specific parameter of dispatch, scheduling, and/or utilization by adjusting a safety margin metric (e.g., increasing/decreasing safety margin will increase/decrease underlying values associated with delivery, feedstock site selections, etc. to provide a volumes and utilization more/less resilient to event stress, among other options).

According to some embodiments, the system is configured to implement a proposed schedule automatically absent any user modification or override. As shown in FIG. 1, the dispatching processing includes operations for acceptance or rejection by participants in the distribution (e.g., at 120). In some examples, the system can include an application programming interface to participant systems (e.g., transport systems, feedstock source systems, etc.), that enable accept/reject status to be communicated in response to dispatch requests/schedules. The accept/reject can be presented in the UI as selectable option and can include an adjust selection option to edit a displayed schedule. In response to a reject status, the machine learning model can be used to update the optimal delivery schedule (e.g., at 116) to account for the rejected element of the schedule, and dispatching can be executed based on the updated schedule at 118. In some embodiments, updates can trigger notices to end users to facilitate review and acceptance of any updated schedule.

As shown in FIG. 1, a material need projection can be used at 112 to determine an optimized schedule 114 leveraging a dispatching model 116. In other embodiments, the optimization can occur in conjunction with dispatching, and even an optimal distribution/routing can be used to back into a determination that a sufficient material need will be met to sustain renewable gas conversion/production given the dispatching schedule.

The material need projection can include statistical models for any number of processing sites (e.g., 104-110) to set a baseline for material needs. In further examples, statistical models based on historic data can be used to set a baseline and safety margin to ensure material availability is not a limiting factor in production. In some embodiments, the statistical models can be used as a benchmark for machine learning approaches. In other embodiments, machine learning models can be trained to include active or real time data while statistical models are used. Data collection can include sensor systems and/or real time data collection. Once the machine learning models are trained, the system can use the machine learning models to further optimize processing, for example, by generating a material need projection for any number of processing sites.

According to some embodiments, the system can include a recommendation component (e.g., 130) that uses the outputs of the dispatching model and/or material need projection model to output a recommendation (e.g., 132) regarding optimal use of resources that optimize renewable energy production at respective processing sites. In some other embodiments, the recommendation component is configured to generate a projected output on a site-by-site basis and compare the site-by-site output to determine the recommended site for a specific feedstock stream. Some embodiments enable management on a feedstock stream by stream basis, using a determination of which stream is optimal at which processing site. The determination can evaluate the use of resources to deliver the stream to the site. For example, stream A may be optimal at site 104, but the transportation resource required makes the allocation sub-optimal. In various embodiments, system resource utilization can be encapsulated or associated with a cost (e.g., cost for transport includes greenhouse gas emissions generated in addition to the transportation resources), and the model or recommendation can be trained to reduce the costs associated with the optimal renewable gas production. In some examples, the UI can be configured to adjust optimization parameters, including optimization of renewable gas production and elimination of other considerations (e.g., greenhouse gas emissions resulting from projected/current operation). The UI can also be configured to mandate usage of a particular feedstock location and/or stock volume as part of the optimization determination. In some examples, mandated values can reduce the complexity of the optimization calculation.

Other embodiments can include models that are trained on specific site operation data. For example, a site model can be trained on internal conditions/data at the site (e.g., material volumes, mixing frequency, carbon nitrogen ratio, chemical oxygen demand, total volatility solids, total solids, FOG, DAF, brewery, quality metrics, among other options), and external conditions for the site (e.g., weather, humidity, season, daylight hours, temperature, etc.) and output a prediction regarding renewable gas production for the given inputs. Various embodiments of the model can be configured to predict output based on subsets of the preceding input, and with various combinations of the preceding variables. Some examples are configured to output predictions based on a subset of the internal conditions and any one or more external conditions, and other models can provide sufficiently accurate predictions based on one or more external conditions coupled with any combination of the internal data sources.

In some other embodiments, the system can include models that are trained to output a minimum level of inputs to a processing site to achieve a desired renewable gas output. Such models can be trained to include external factors. In still other embodiments, a time of operation is used to model how external factors impact production input needs and/or optimization of output production.

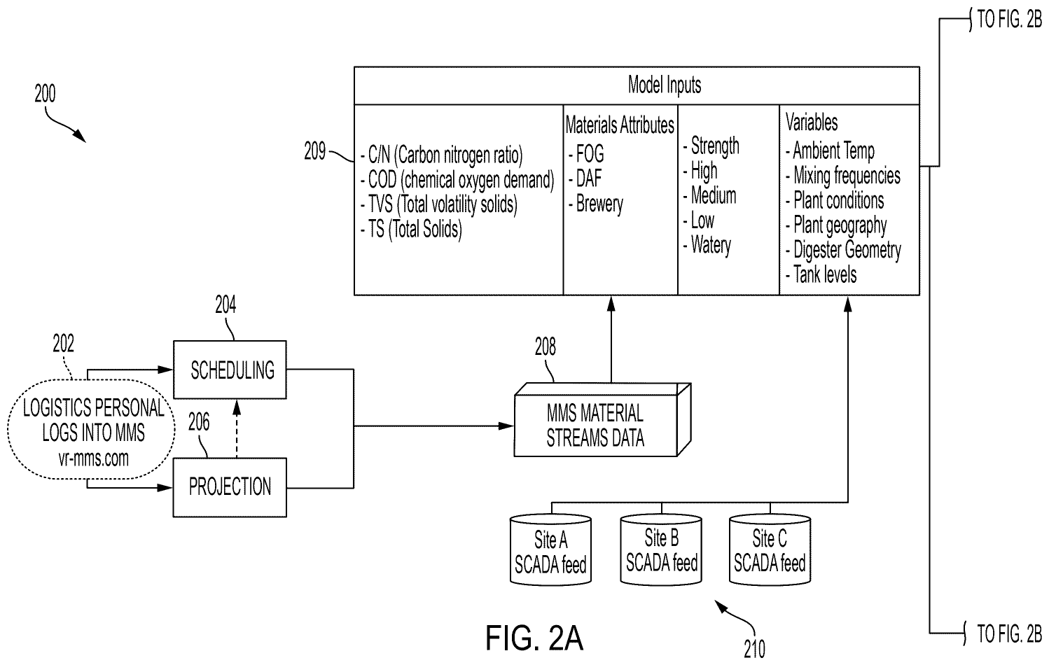

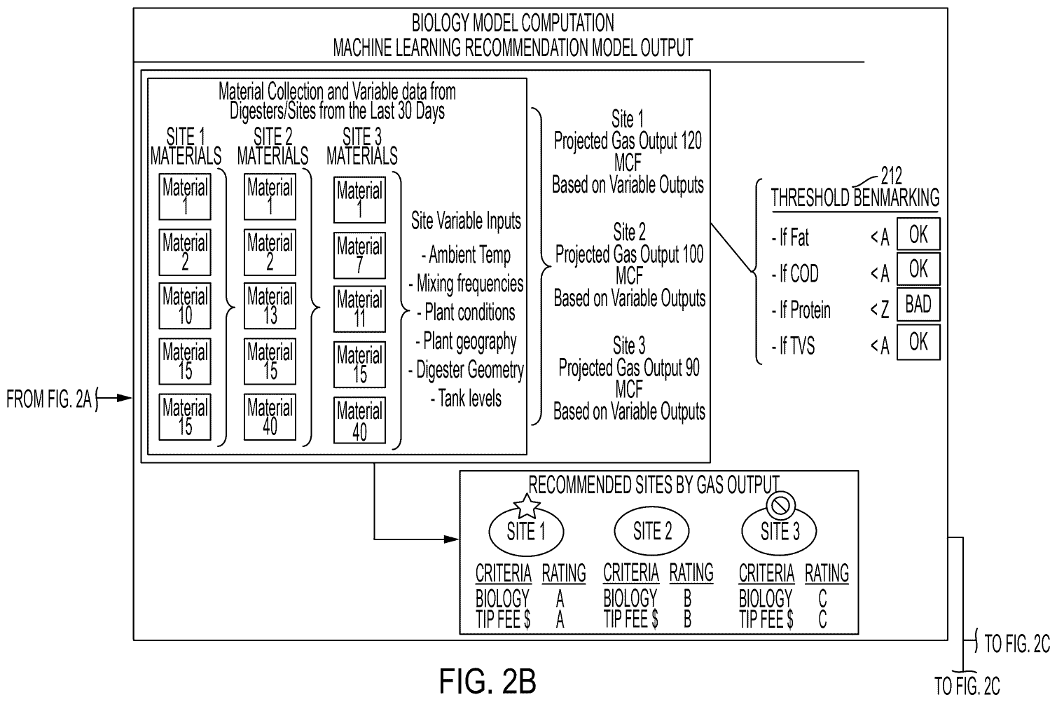

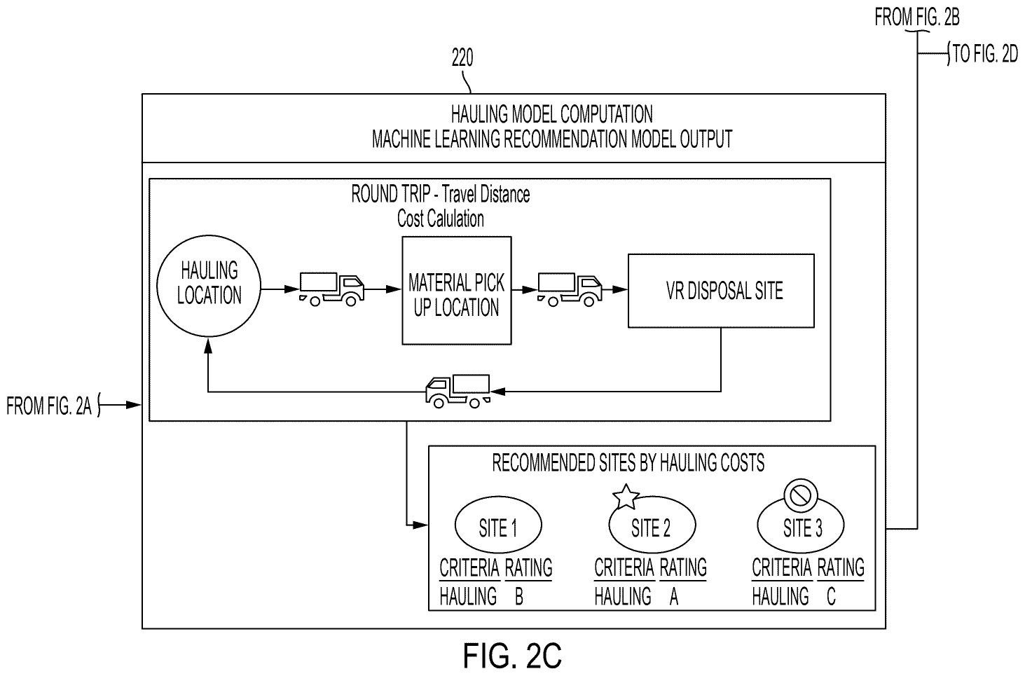

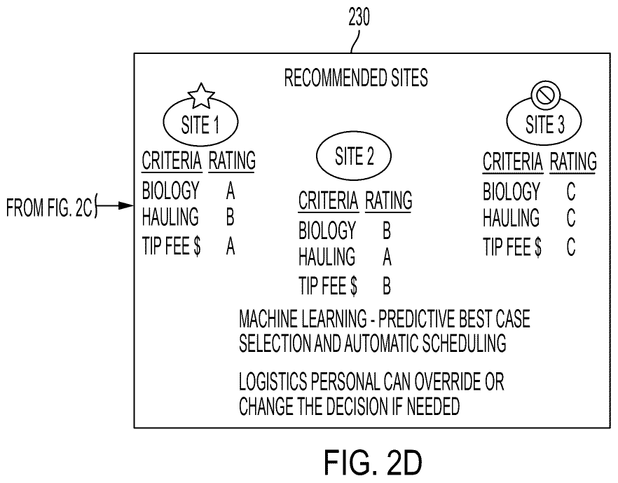

FIG. 2 illustrates further optimization implementation for a renewable energy (e.g., renewable gas) conversion system. FIG. 2 is a block diagram of example system component and process flow. End users can access the system, for example, at 202 via a web interface, the internet, internal portal, or a locally executing program among other options. Once the end user has access to the system, the end user can access scheduling and projection functions to optimize renewable gas production at a plurality of processing sites based on any number of available feedstock streams.

According to one embodiment, the scheduling functionality can include machine learning models that are configured to optimize a dispatch schedule for the plurality of feedstock streams and respective locations. Where the feedstock streams are to be delivered to the plurality of processing sites and their respective locations. The scheduling functions, at 204, can include machine learning models that accept a projected need or desired delivery volume of material for processing and optimize the scheduling and transport to respective processing sites. Shown at 206, the system can include projection functions to identify a minimum level or target level of material need for respective sites to produce optimal renewable gas outputs. According to some embodiments, the projection functions at 206 can include machine learning models that are tailored to the biologic functions at respective processing sites.

For example, a biologic model can include and/or be trained on specific characteristics of the processing site to predict an optimal renewable gas output associated with those characteristics. In some examples, the model inputs can include C/N (carbon nitrogen ratio), COD (chemical oxygen demand), TVS (total volatility solids), and TS (total solids), among other options. In other embodiments, the model can include training on FOG (fat, oil, grease), DAF (dissolved air flotation slurry), Brewery, etc. FOG, DAF, and brewery define the materials attributes that can be used in optimizing production predictions of various models.

Other inputs can include attributes of specific materials that rate the quality of the respective material. For example, the ratings can include strength, high, medium, low, watery, among the other options. The quality associated with a respective feedstock source can be sampled via sensors or during a sampling process. In some embodiments, the sampling process can be used to ensure consistent quality and also to improve modeling characteristics.

Various models can also be trained on external conditions or variables. For example, machine learning models can be configured to predict a renewable gas output based on inputs that include ambient temperature, common mixing frequencies, plant conditions, plant geography, digester geometry, tank levels, among other options. Shown in FIG. 2A, these various inputs can be defined as a materials stream data at 208 which can be used to train models, such that the models can predict an output of renewable gas production for a given set of inputs. In various embodiments, a plurality of models can be trained on a plurality of respective processing sites. For example, each site can be associated with one model and the plurality of models can be executed to determine which amongst the plurality of sites would produce an optimal output for a given set of inputs and conditions.

Shown in FIG. 2A at 210, SCADA feeds provide processing data for a set of respective processing sites (e.g., Site A, Site B, and Site C). The SCADA feeds provide supervisory control and data acquisition information for each of the sites and can be associated with a series of sensors that capture data in real time and report back on characteristics of the various processing sites. These characteristics can be incorporated into the machine learning and training of respective models. Once incorporated the models produce more accurate predictions on a renewable gas output produced for a given set of conditions and inputs. System and flow 200 continue on the upper branch to FIG. 2B. FIG. 2B illustrates an example of a biology model and computation used to optimize renewable gas output and resource utilization for gas conversion. Shown at 212, each site has a set of associated materials, and the machine learning model can be trained to optimize the output for each of the respective sites. Given the set of materials that are available, and site variable inputs the model can predict a given renewable gas output. The system can tailor such inputs until an optimal level is achieved. In some embodiments, the site variable inputs can include ambient temperature, common mixing frequencies, plant conditions, plant geography, digester geometry, tank levels, among other options.

At 212, for a given set of materials and respective volumes of same, and/or external condition inputs, the machine learning models are configured to predict an output for each site. In various embodiments, the system models can be configured to identify the volume of material needed at respective sites to produce the respective or a desired output. Further embodiments can be configured to identify threshold or benchmarking information associated with the renewable gas outputs being produced. For example, where fat volume or concentration is greater than a specific threshold the model can determine that that range is sufficient for optimal production. In other examples, sufficiency can be determined in conjunction with external factors described above. In another example, the model can be configured to determine that a COD range or threshold (e.g., based on volume or concentration) is sufficient for optimal production. Likewise, where protein concentration or volume is less than a threshold amount the machine learning model can identify that optimization is available or improved production would be achieved given additional input of that material. In another example, if TVS is less than a threshold amount, the machine learning model can identify that that threshold is sufficient for optimal production. Each of these thresholds can be generated for respective sites. In some embodiments, optimal conditions and material requirements vary according to the processing sites and potentially differing external factors, among other options.

Process 200 proceeds along two forks, the upper fork to FIG. 2B and the lower fork to FIG. 2C. FIG. 2C shows a hauling model computation at 220. The hauling model is an example of a dispatching model described above. The hauling model is configured to optimize resource utilization when determining how to deliver material to respective processing sites. In some examples, the hauling model is configured to optimize a cost evaluation. In some embodiments, “cost” is associated with the respective resources used by the system in order to produce a specific renewable gas output. By optimizing on cost as an indirect indicator of resources, the system is configured to generate an optimal usage of transportation resources, limiting transportation time and distance, and even in some examples, optimizing distribution to reduce greenhouse gas emissions produced when distributing material to respective processing sites.

At 230, shown in FIG. 2D, the results of the two models are combined to identify a recommended distribution of material to respective sites, that achieves optimal renewable gas production and optimal resource utilization across the plurality processing sites. According to some of the embodiments, the biology and hauling models can be executed as a combined model that produces the output recommended distribution for any number of processing sites. In further embodiments, the machine learning models can be implemented as an artificial neural network (“ANN”) that are trained on the identified inputs to produce respective renewable gas production output predictions. For example, an ANN can be used to train on material availability and account for external factors to predict a renewable gas output. In other embodiments, a deep neural network (“DNN”) can be trained on the same inputs to predict specific renewable gas outputs. Other model architectures can be used and be trained on material and external factor inputs to deliver an optimal output prediction.

According to some embodiments, the system can be configured to use such models to determine material needs at respective sites. Using the predicted material needs, determine an optimal routing, for example, with a distribution machine learning model. As discussed above, some models can be trained on costs associated with resource utilization. In one example, greenhouse gas emissions can be associated with a specific cost, including greenhouse gas emissions generated during transportation of feedstock.

In some embodiments, users can access the system and assign their own weights or values for such costs. With customizable cost values or weightings, the machine learning model is configurable based on user preference to weight greenhouse gas emissionscosts more heavily when determining optimal distribution or renewable gas production. By providing a heavy weight or cost to greenhouse gas emissions, the system enables renewable energy production to have the least environmental impact. Such opportunity and functionality are not available with conventional implementation and, for example, provides improvements in greenhouse gas emission control unavailable in conventional approaches. Specific UI are provided by the system to enable user to change weighting, emphasize optimization, or adjust computed optimizations, among other options. In some examples, user can access visualizations in the user interface that are configured to adjusting weighting values by selecting a visual indicator (e.g., low to high importance, weighting value low to high, etc.). Manipulations of a slider or within a visualization scale is translated automatically into decreased or increased values (e.g., including weighting values, among other options). In other embodiments, users can directly input values to manage or update model predictions, and/or retrain models to specified preference, among other options.

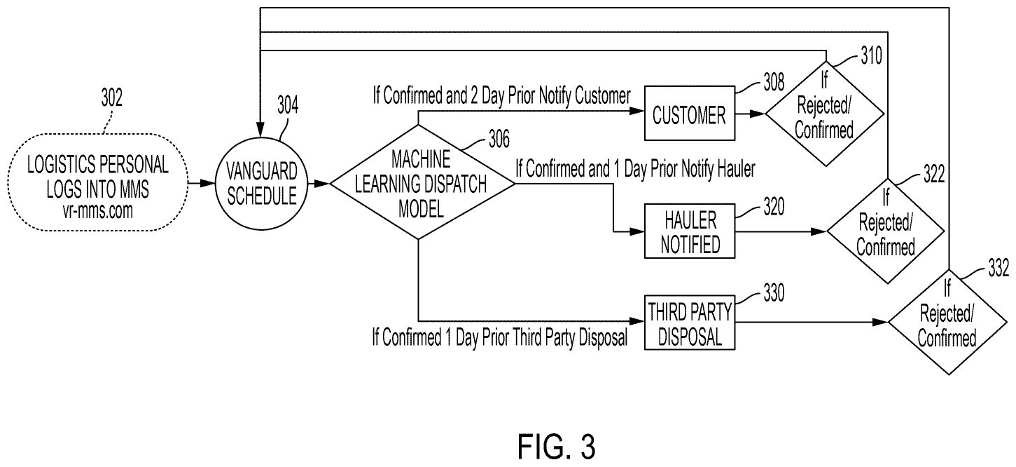

FIG. 3 is an example process flow 300 for dispatching material to processing sites, according to one embodiment. Process 300 can optionally begin at 302 with an end user accessing the system. The end user can access the system via the Internet, intranet, a web application/interface or locally installed app on the user's computing device. Step 302 is optional, for example, as the process 300 will execute without user intervention based on automatic settings. The end user can observe a defined schedule at 304, or the system can access a defined schedule at 304.

The schedule is defined using a machine learning model at 306. According to some embodiments the machine learning model is configured to optimize scheduling of the transportation of materials to respective processing sites as discussed herein. The machine learning model is configured to build a candidate schedule and automate its execution via the participants in the gas conversion process. According to one embodiment, the customer supplies feedstock that is used as source material for the conversion to gas process. The customer 308 is requested to approve a specific schedule in advance of a pickup. According to one embodiment the customer can confirm or reject a potential scheduled event at 310, and the associated status is used to update a candidate schedule. If confirmed the schedule event is executed absent a modification or a redetermination of an optimal schedule (e.g., based on other rejections and/or confirmations).

As shown, a hauler or transportation entity 320 is also notified of potential schedule events. At 322, the transportation entity can accept or reject a proposed scheduled event. The status is returned to the system and if accepted the scheduled event is confirmed, and if rejected the system can trigger the machine learning dispatch model to regenerate a candidate schedule with the constraint associated with the rejected schedule event. According to some embodiments, execution of process 300 may also include third-party disposal (e.g. at 330). The third-party disposal sites can accept or reject a scheduled event at 332. The associated status is returned to the system and incorporated into any schedule at 304. Just as with hauler and customer accept/reject status the system can be configured to invoke the machine learning model to regenerate a candidate schedule based on any return status, under any communicated restraints constraints.

Various embodiments implement machine learning models to emulate/predict characteristics of a digester/hydrolyzer. The prediction of how the digester/hydrolyzer operates enables improved functionality over many conventional approaches. Conventional approaches may vary operational parameters, but test and see approaches are inefficient, prone to errors, and can even be taxing on physical production equipment (e.g., shorten useful life of system components). Various embodiments described herein ensure consistent delivery of feedstock and provide for optimization of sources for use, as well as optimization of resources required to transport those sources. In various embodiments, the system can prioritize highest quality, production properties, and tailor delivery of the same for optimal usage, improving over various known approaches.

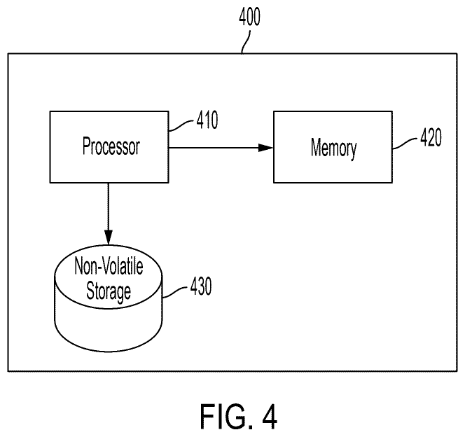

FIG. 4 is a block diagram of an example computer system that is improved by implementing the functions, operations, and/or architectures described herein. Modifications and variations of the discussed embodiments will be apparent to those of ordinary skill in the art and all such modifications and variations are included within the scope of the appended claims. Additionally, an illustrative implementation of a computer system 400 that may be used in connection with any of the embodiments of the disclosure provided herein is shown in FIG. 4.

The computer system 400 may include one or more processors 410 and one or more articles of manufacture that comprise non-transitory computer-readable storage media (e.g., memory 420 and one or more non-volatile storage media 430). The processor 410 may control writing data to and reading data from the memory 420 and the non-volatile storage device 430 in any suitable manner. To perform any of the functionality described herein (e.g., optimization of renewable energy output, minimization of greenhouse gas emission, training of biology models, training of dispatching models, etc.), the processor 410 may execute one or more processor-executable instructions stored in one or more non-transitory computer-readable storage media (e.g., the memory 420), which may serve as non-transitory computer-readable storage media storing processor-executable instructions for execution by the processor 410.

The terms “program” or “software” are used herein in a generic sense to refer to any type of computer code or set of processor-executable instructions that can be employed to program a computer or other processor to implement various aspects of embodiments as discussed above. Additionally, it should be appreciated that according to one aspect, one or more computer programs that when executed perform methods of the disclosure provided herein need not reside on a single computer or processor, but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in one or more non-transitory computer-readable storage media in any suitable form. For simplicity of illustration, data structures may be shown to have fields that are related through location in the data structure. Such relationships may likewise be achieved by assigning storage for the fields with locations in a non-transitory computer-readable medium that convey relationships between the fields. However, any suitable mechanism may be used to establish relationships among information in fields of a data structure, including through the use of pointers, tags or other mechanisms that establish relationships among data elements.

Also, various inventive concepts may be embodied as one or more processes, of which examples (e.g., the processes described herein) have been provided. The acts performed as part of each process may be ordered in any suitable way. Accordingly, embodiments may be constructed in which acts are performed in an order different than illustrated, which may include performing some acts simultaneously, even though shown as sequential acts in illustrative embodiments.

In other embodiments, various ones of the functions and/or portions of the flows discussed herein can be executed in different order. In still other embodiments, various ones of the functions and/or portions of the flow can be omitted, or consolidated. In yet other embodiments, various ones of the functions and/or portions of the flow can be combined, and used in various combinations of the disclosed flows, portions of flows, and/or individual functions. In various examples, various ones of the screens, functions and/or algorithms can be combined, and can be used in various combinations of the disclosed functions.

FIG. 5 is an example process flow 500 for implementing logistic scheduling. As shown, process 500 begins at 502 with an authorized user accessing the system. Process 500 continues at 504 with presentation and display of the schedule for an anaerobic digester. The schedule can be created by machine learning models and/or adjusted by administrative users as discussed above. Process 500 continues with dispatch functionality at 506 (e.g., model to dispatch schedule, optimized and/or adjusted dispatch schedule, among other options). As part of dispatching at 506 customers (feedstock suppliers) can be notified of the potential dispatch schedule at 550 via email or other communication modality. Dispatch functionality of 506 can also include notification to the hauler to confirm a schedule at 552 via an email or other communication method and may also include communication between the customers and hauling providers with confirmation/return communication at 554.

According to some embodiments, process 500 can continue with capture of status associated with receipt and/or acceptance of a particular dispatch schedule at 508. If any part or the entire schedule is not accepted 510 No, the process continues by establishing whether the rejection was based on the system (at 514) or due to a customer rejection at 516 and in some embodiments in case of rejection by both. Additional dispatching and/or scheduling operations can be re-executed based on any rejected portion or a rejection of the entirety of the scheduling (not shown).

According to further embodiments, if the particulars of a dispatch schedule are accepted at 510 yes process 500 continues by updating or recording status at 520. According to some embodiments, process 500 can continue with management of additional operations including, for example, invoice communication at 522 from a hauler (e.g. confirmed via 552-554). Process 500 can continue with receipt of the additional information by updating or setting a status to complete at 524. Process 500 may also include processing of invoices at 526 and an update to an associated record to show status invoiced at 528. Process 500 concludes at 530.

FIG. 6 is an example process flow 600 for implementing logistic scheduling. As shown process 600 begins at 602 with an authorized user accessing the system. Process 600 continues at 604 with the presentation of display of a schedule for an organic's receiving area (“ORA”). As part of the displayed schedule a set of dispatch operations can also be generational shown at 606. In some embodiments the dispatch operations have been generated by machine learning model to optimize resource utilization throughout a production chain.

According to one barman, as part of the sponsoring of 606 customers (the feedstock suppliers) can be notified as well as haulers notified of the potential dispatch schedule. At 650, the process can continue with additional information and receipt of same. One example an invoice from a hauler can be received at 650 and a system status updated to completed at 652 based on a dispatch schedule, invoicing and execution. In further example, one status is updated in 652 process 600 can continue with invoice processing at 654, and updated status at 656 (e.g., “invoiced”).

In further embodiments, a dispatch schedule in respect of operations generated in 606 must be loaded received or accepted for example at 608. According to one embodiment, if any of the operations or portions of the schedule are not accepted at 610 no process 600 continues with a notification to the generator (e.g. 612) and any received materials can be returned at 614. If the various operations are accepted at 610 gas process 600 continuous at 620 with an updated status of “complete”. In some examples, source materials can be received as a pass-through. For example, if it is a pass-through feed shown at 622 yes the system adds pricing information at 626 and updates a schedule to final status at 628. If the source materials received are not passed through at 622 No the schedule is finalized at 624 the finalize schedule can be used as part of the dispatching and confirmation of same (e.g. 650 through 656). Once confirmed a status can be updated to “invoiced” at 656 and process 600 can be complete at 658.

FIG. 7 is an example process flow 700 for implementing logistic scheduling. As shown, process 700 begins at 702 with an authorized user accessing the system. Process 700 continues at 704 with presentation and display of the schedule for an anaerobic digester. The schedule can be created by machine learning models and/or adjusted by administrative users as discussed above. Process 700 continues with dispatch functionality at 706 (e.g., model to dispatch schedule, optimized and/or adjusted dispatch schedule, among other options). As part of dispatching at 706 customers (feedstock suppliers) can be notified of the potential dispatch schedule at 752 via email or other communication modality. Dispatch functionality of 706 can also include notification of the hauler to confirm schedule at 754 via an email or other communication method and may also include communication between the customers and hauling providers with confirmation/return communication at 756. In some embodiments, dispatch functions determined at 706 can include disposal dispatch operation. For example, any disposal requirements (e.g., 750) can be included and computed in an optimize disposal scheduled (for example, generated via machine learning models as described above). Such dispatch operations are communicated to needed disposal sites at 750 and can be confirmed via communication at 756.

According to some embodiments, process 700 can continue with capture of status associated with receipt and/or acceptance of a particular dispatch schedule at 708. If any part or the entire schedule is not accepted 710 No, the process continues by establishing whether the rejection was based on the system (at 714) or due to a customer rejection at 716 and in some embodiments in case of rejection by both. Additional dispatching and/or scheduling operations can be re-executed based on any rejected portion or a rejection of the entirety of the scheduling (not shown).

According to further embodiments, if the particulars of a dispatch schedule are accepted at 710 Yes process 700 continues by updating or recording status at 720. According to some embodiments, process 700 can continue with management of additional operations including, for example, invoice communication at 722 from a hauler (e.g., additional information may also come from communication received as part of 750-756). Other additional information can be received at 724 YES Process 700 can continue with receipt of the additional information by updating or setting a status to complete at 726. Process 700 may also include processing of invoices at 728 and an update to an associated record to show status invoiced at 730. Process 700 concludes at 732.

FIG. 8 illustrates another process flow 800 for managing renewable energy production. Process 800 is configured to manage strategic partners who can be identified within the system based on consistent supply of feedstock, consistent quality, or other optimization targets. Process 800 beings at 802 with access to the system by an authorized user. At 804, specific generator information can be record or access by the user. Available feedstock stream can be defined or accessed at 806. Strategic partners are typically characterized by having recurring loads (e.g., feedstock) available for processing. Any such recurring data can be captured or reviewed at 810 and includes characterization of the recurring information. Including for example the current type which can be daily weekly bimonthly monthly among other options. Information on scheduling including days of the week a particular source or feedstock would be available. Other information can include sequencing information potential disposal sites or a digester tank to which source materials will be delivered.

At 812, characteristics for the strategic partner can be specified, including, for example, information on acceptance requirements (e.g., one day prior to scheduling, transportation, etc.). Various conditions can be specified at 812 include various notice time periods, as well as automatic acceptance criteria. Once decisioning information has been specified and potentially satisfied, the “load” information (e.g., delivery type, volume, characteristic, etc.) can be added to use in projections at 814 YES, and integrated into automatic scheduling operations at 818, and process 800 can end at 820. If there are validation issues or criteria is unmet a potential load of feedstock supply may not be added (e.g., 814 No) and records deleted from projection information at 816.

According to various embodiments, the system and process flows described can utilize machine learning models that generate predictions for renewable gas output for a given input to one or more digester sites, generate prediction on needed input volumes, sources, and/or sites for a specified renewable gas output (which can be based on a prediction of renewable gas output), the predictions can be specific to respective digesters, digester sites, etc. Further models can generate optimal routings for any predicted need, and can include safety margins to ensure a predicted need is met. These predicted can be generate on a site by site basis as well as across a plurality of locations/sites/digesters.

### Example Machine Learning Implementation

According to various embodiments, systems and methods are tailored to optimize the conversion of feedstock into renewable energy (e.g., renewable gas). According to some embodiments, the system trains and utilizes machine learning models to optimize renewable energy production of one or more digesters. Stated broadly the system and any material planning functions are tailored to effectively maximize renewable gas output can also optimize on resource utilization for that output (e.g., via, tip fee, hauling costs, etc.). In various examples, certain fees and pricing are used in modeling to reflect systematic resource utilization, and optimizations that improve (e.g., reduce) those costs are directly correlated to improved utilization of the associated system resources (e.g., landfill, hauling equipment, greenhouse gas emissions produced by operation of the same, etc.). Various costs inputs (e.g., hauling costs, landfill utilization (e.g., tip fee), etc.) are modelled to improve and optimize utilization of respective resources, system component, etc.

According to one embodiment, a digester model can be trained to predict and optimize operations of a respective digester at a given location. Some models can be trained on multiple digesters at a given site and/or multiple sites. In further example, a trained model can be used to predict operation of similar sites and/or similar digesters, including those have similar operating parameters. In still other embodiments, a trained digester model can be specific to a site, and can also be used a baseline model for further training to operations on another site.

According to one embodiment, a digesters models is constructed that uses the values of digester parameters (e.g., pH, VFA, TIC, Temp, etc.) from one day before the model execution date to predict the renewable gas output. This approach can be used to simplify processing and computation, and operations under the assumption that these values will not change dramatically over time. Returned results have shown sufficient accuracy to implement the digester model to optimize products. Further embodiments employ the digester ML model as a real time model, by using real-time digester parameters (e.g., pH, VFA, TIC, Temp, etc.) and have returned improved accuracy. Various digester sites provide sensors data to capture real time data that is used to optimize digester execution, and further to train, predict, and validate digester models. As new data is captured for digester operation, the models can be re-trained on a rolling basis, the models accuracy determined, and the retrained models used where performance increases and/or accuracy is improved. In one example, the ML model is retrained every 15 days to learn the data variances from associated digesters. Other examples use other time frames (e.g., five days, ten days, 20, 30, 40, 50, etc.).

According to various embodiments, the initial data capture from a digester site is evaluated and filtered to reduce noise, identify outlier values, and/or resolve missing data issues. Shown below in Table 1 and 2 are percentages of missing values for an example set of variables for a capture lasting a specified time window (e.g., 15 day, 30 day, etc.) that can be used to train a prediction model.

TABLE 1
Example Digester “N”

| | |
|---|---|
| BiogasTarget | 0.23% |
| MethaneFlare | 1.13% |
| DigesterTemp | 0.23% |
| AD_PH | 0.11% |
| AD_ORP | 35.71% |
| VFA | 35.71% |
| TIC | 35.71% |
| OLR | 0.0% |
| SSO_Dosing_Tpd | 0.56% |
| Report_Date | 0.0% |
| COD | 0.0% |
| avgfat | 0.0% |
| avgprotein | 0.0% |
| avgcarbohydrates | 0.0% |
| avgTS | 0.0% |
| avgTVS | 0.0% |
| avg_C_N_Ratio | 0.0% |
| fat | 1.13% |
| protein | 1.13% |
| carbohydrates | 1.13% |
| C_N_Ratio | 1.36% |
| TS | 1.13% |
| TVS | 1.13% |
| dtype: object | |

TABLE 2
Example Digester “S”

| | |
|---|---|
| BiogasTarget | 0.23% |
| MethaneFlare | 100.0% |
| DigesterTemp | 0.23% |
| AD_PH | 0.11% |
| AD_ORP | 29.27% |
| VFA | 29.27% |
| TIC | 29.27% |
| OLR | 0.0% |
| SSO_Dosing_Tpd | 0.56% |
| Report_Date | 0.0% |
| COD | 0.0% |
| avgfat | 0.0% |
| avgprotein | 0.0% |
| avgcarbohydrates | 0.0% |
| avgTS | 0.0% |
| avgTVS | 0.0% |
| avg_C_N_Ratio | 0.0% |
| fat | 1.13% |
| protein | 1.13% |
| carbohydrates | 1.13% |
| C_N_Ratio | 1.36% |
| TS | 1.13% |
| TVS | 1.13% |
| dtype: object | |

The data can be normalized to improve the training data set before the values are used to train respective models. According to some embodiments, the following values have been normalized to improve the training data set and the resulting models:
Digester Temperature (Capping using Box and Whisker Plots)
AD_PH (Imputing zeros/missing values with nearest non-zero values. Shown using Kernel Density plot—KDE plot)
SSO Dosing TPD (Capping using Box and Whisker Plots)
AD_ORP (K-Nearest Neighbors (knn) imputation. Shown using histogram)
VFA (K-Nearest Neighbors (knn) imputation. Shown using histogram)
TIC (K-Nearest Neighbors (knn) imputation. Shown using histogram)
CN Ratio (Capping using Box and Whisker Plots)
COD (Median Imputation. Shown using histogram)
OLR (Median Imputation. Shown using histogram)
   In this example, data is processed using an imputation method: clipping to whiskers (e.g., lower bound=Q1×1.5*IQR, Upper bound=Q3+1.5*IQR). The result provides training data having reduced outlier impact and improved imputation accuracy, and in further example, having training data values that are more representative. Observations under execution (e.g., train, predict, validate): the values that are much further away in the left graph are more centered in the right graph and representative of actual digester temperature.

In further embodiments, AD_PH (digester PH) value is normalized via imputing zeros/missing values using the nearest non-zero values of PH. In some examples, this missing value resolution by filling zero values, improve imputation accuracy and results in values that are more representative), weekend values are resolved. Table 5 and 6 illustrate before and after:

In other embodiments, that training data can be improved with kernel density plotting to resolve missing data issues. For example, AD_PH can be processes to impute values where zero or missing using the nearest non-zero value for pH—shown in Table 7 (before) and Table 8 (After).
In further embodiments, the source separated organics (SSO) doping Targeted Protein Degradation (TPD) variable is processed to reduce outlier impact and improve accuracy. In one embodiment, SSO_doping_TPD values are imputed by clipping to whiskers (e.g., setting a lower bound=Q1−1.5*IQR, and setting an upper bound=Q3+1.5*IQR).

In other embodiments, normalization operations can include additional imputation methodologies (e.g., K-nn (known nearest neighbor, etc.) using values of another parameter. For example, volatile fatty acid (“VFA”) parameter had 36% missing values in the Table 1 & 2 examples. The KNN imputation was used to resolve, and produced accurate results in modelling (e.g., based on SSO-Dosing values). The TIC (Alkalinity, total inorganic carbonate buffer) parameter and values likewise employed adjustments (e.g., based on SSO-Dosing values). including adjustments based on KNN. ORP (Oxidation-Reduction Potential) values were processed under KNN methodology and values for SSO-Dosing. In the ORP example, resulting values close to 0 were still well represented and missing values (in ORP column) used SSO Dosing to define the neighborhood (e.g., 5 values) to impute a flow of values in the range without gaps. Other windows can be used for determining neighbors (e.g., 2, 3, 4, 6, 7, etc.). In some examples, data captured on CN (Carbon-to-nitrogen) Ratio can be filtered to resolve outlier impact and improve imputation accuracy. For example, clipping to whiskers methodologies can be employed on the training data to provide better representative data. In other examples, COD training data can be improved via median imputation. Median imputation can be used to replace missing values with the median of the non-missing values in the feature, making it more robust to outliers (e.g., more robust than mean imputation). In other examples, mean imputation can be used with chemical oxygen demand (“COD”). In various training data sets it was observed that COD was not overly subject to missing values, and imputation methodologies were not executed. In still other examples, imputation for training data values for Avg carbon to nitrogen “CN” ratio was employed. In Avg CN Ratio capping using Box and Whisker Plots was employed to reducing outlier impact and improve imputation accuracy (e.g., with resulting values being more representative).

In other examples, organic load data (“OLD”) values were generated via median imputation. Median imputation can be used to replace missing values with the median of the non-missing values in the feature, making it more robust to outliers (e.g., found to be more robust than mean imputation). In other examples, mean imputation can be used with OLD. In various training data sets it was observed that OLD was not overly subject to missing values, and imputation methodologies were not executed. Renewable gas output production used in the machine learning models was captured by defining target variables and creation over an average measurement and time window of ten days from when materials (e.g., feedstock) enter a respective hydrolyzer/digester. Table 9 illustrates an example of target variable definition and creation. Table 10 illustrates the correlation between the input variables used in training respective models and the output produced.

According to some embodiments, a plurality of regression models were used to determine correlations and predictions of outputs based on respective inputs. For example, simple linear regressions were executed to predict a continuous outcome variable based on a single predictor variable using a straight line. In other examples, multiple linear regression approaches were used to predict a continuous outcome variable based on multiple predictor variables using a linear equation. Other example included random forest approaches that generate an ensemble learning method that creates multiple decision trees on different subsets of the data and averages their predictions for improved accuracy and robustness) and XGBoost approaches that generate a gradient boosting algorithm that iteratively builds an ensemble of weak prediction models (typically decision trees) by focusing on the errors of previous models. While the various example approaches were used an validated using R-squared, Adjusted R\hat{ }2, mean absolute error (MAE), root mean squared error (RMSE), and mean absolute percentage error (MAPE) metrics, and provide viable options for execution XGBoost (“extreme gradient boosting”) achieved the best performance and was used in various implementations to train new prediction models using the data and variables described above. In other implementation subsets of the parameters described above were used to generate and execute similar models (e.g., having 3, 4, 5, 6, 7, 8, and 9 variables selected from the group of variables described above).

In some other embodiments, deep learning models were explored to generate prediction on renewable gas output for a given set of inputs. A variety of artificial neural network (“ANN”) models were executed to train on the inputs and subsets of the inputs described above. Models with a single hidden layer as well as models with two hidden layers were trained and used to predict. Similar performances were observed in the deep learning models, however XGBoost approach yielded better performance for the data collection utilized (e.g., two year window of digester performance). An example architecture for a neural network was used with a input layer having a number of neurons equal to the number of predictors (e.g., variables above) of gas output. Embodiments of the neural network included a hidden layer 1 and different numbers of neurons (e.g., 50, 100, 200, etc.) coupled to a hidden layer 2 (e.g., can be optional) to account for more complex relationships. The activation functions used included ReLU (Rectified Linear Unit) with a linear activation for regression, and an output layer of one neuron for predicting the gas output.

Table 11 provides an example of modeling results obtained on a train data set collection over two and half years ((January 2022-July 2024) and a testing time period of July 2024 to October 2024).

TABLE 11

| | MAE | | RMSE | | MAPE | |
|---|---|---|---|---|---|---|
| ModelType | Train | Test | Train | Test | Train | Test |
| Basic | 77,452 | 66,142 | 91,737 | 74,615 | 48.04% | 27.83% |
| Mean | | | | | | |
| Polynomial | 53,361 | 58,495 | 66,365 | 74,221 | 30.72% | 23.51% |
| Regression | | | | | | |
| Linear | 69,219 | 55,510 | 84,221 | 65,312 | 36.19% | 22.45% |
| Regression | | | | | | |
| Random | 31,548 | 47,091 | 48,765 | 58,196 | 16.99% | 19.92% |
| Forest | | | | | | |
| XGBoost | 30,316 | 46,536 | 46,487 | 57,042 | 16.85% | 19.86% |

According to some embodiments, the hyperparameters and other modeling inputs were adjusted to expand on performance information. In some implementations, the machine learning models varied according to the following ranges or options (Table 12):

TABLE 12

| Hyperparameter | Ranges Used | Description |
|---|---|---|
| n_estimators | 100-1000 | Number of decision trees in the |
| | | forest. Higher values improved |
| | | performance but can increase |
| | | computational time. |
| max_depth | None or a | Maximum depth of each tree. A |
| | value between | larger value allows for more complex |
| | 1 and 100 | models increased the risk of |
| | | overfitting. |
| max_features | sqrt’ or ‘log2’, | Number of features considered |
| | or a fraction of | at each split. ‘sqrt’ or ‘log2’ are used, |
| | the total | both are evaluated for respective |
| | features | datasets. |
| min_samples_{—} | 10-Feb | Minimum number of samples |
| split | | required to split an internal |
| | | node. A larger value has been |
| | | used in some examples. |
| min_samples_{—} | 10-Jan | Minimum number of samples |
| leaf | | required to be at a leaf node. |
| | | A larger value has been used in |
| | | some examples. |
| bootstrap | True or False | Whether to use bootstrapping, |
| | | which samples data with |
| | | replacement to create each tree. |
| | | True used for stability. |
| criterion | gini’ or | Split criterion used in each |
| | ‘entropy’ | tree. ‘gini’ and ‘entropy’ are used |
| | | choices. |
| class_weight | balanced’ or | Weights associated with classes. |
| | None | ‘balanced’ can be useful for |
| | | imbalanced datasets. |

Various implementations of the models yielded difference performance. Generally stated, certain parameters were observed to have a stronger effect on the outcome of the modeling. Table 14 provides an example of analysis of the contributions to the model for each input feature. As shown, features at the top of the table have a stronger influence on the outcome and the influence is given in decreasing order. The color of points represents the direction of effect (red—more positive, blue—more negative). Smaller sample size or a sample with unusual behavior can be taken and the SHAP plot gives insight on the most impact by a feature and the direction of impact. According to various implementations, the example model (e.g., based on XGBoost) is robust and the importance is distributed across multiple features. Various models can use the more “important” features in selecting subsets of parameters.

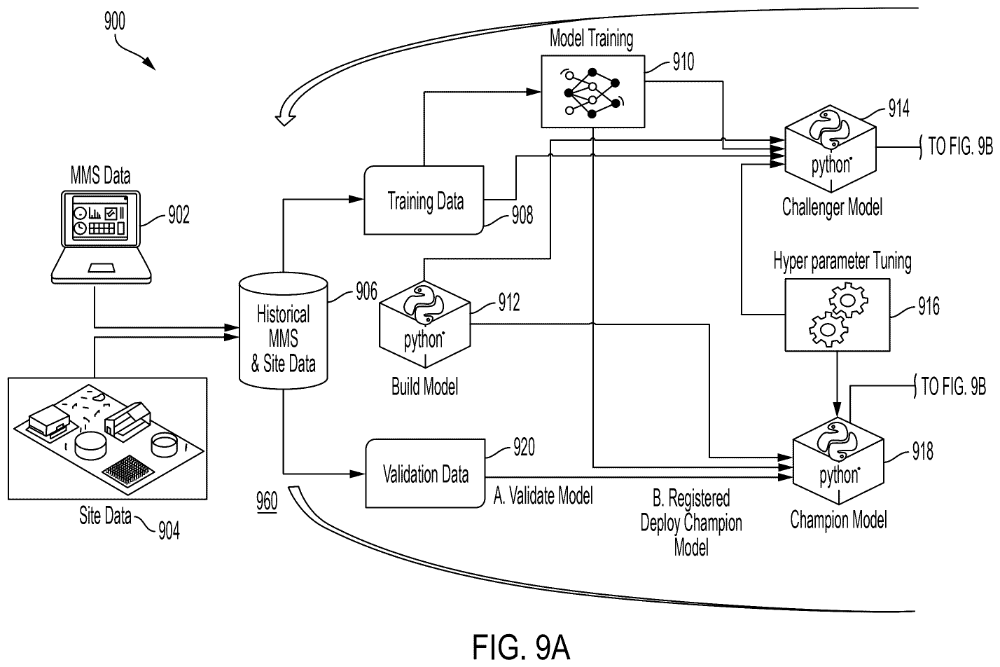

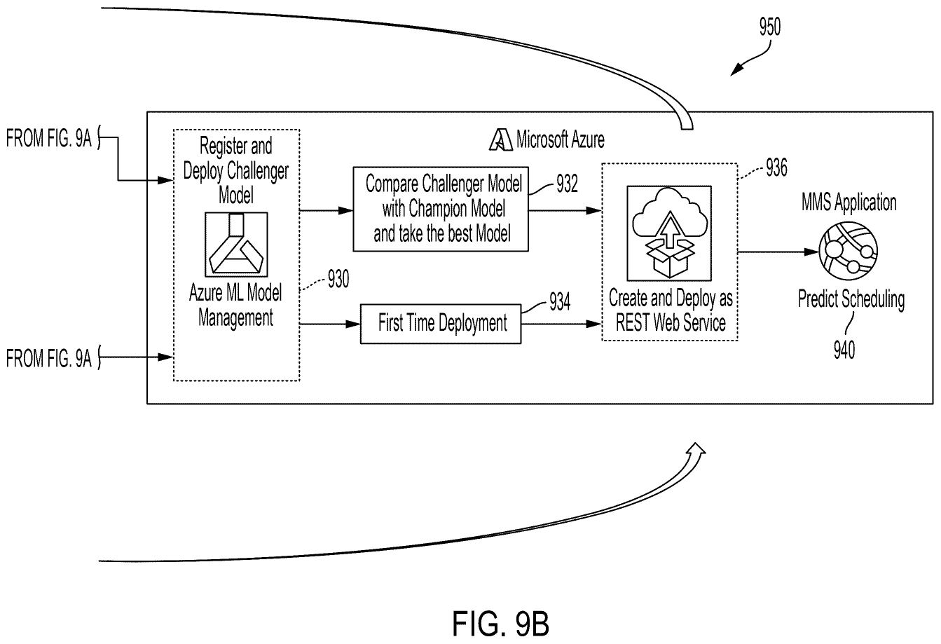

The ML models can be used during execution of a variety of functions and processes to optimize renewable energy (e.g., renewable gas) output. Shown in FIGS. 9A-B is an example process flow 900 with example system elements for implementing and executing machine learning training, updating, and deployment. As shown, process 900 can begin with materials management system (“MMS”) data 902 and site data 904 being captured and/or stored in a database 906 for managing historical MMS and site data. According to one embodiment, the data repository becomes a source of training data (e.g., 908) for building models at 912. The data repository (e.g., 906 is also used for developing validation data (e.g., 920). According to various examples, historical data is broken up into training data groupings and validation data groupings. In further example, the training data can make up the majority of the grouping (e.g., 70 to 85%) and the validation data based on what remains.

As shown, model training can be executed at 910 using the training data obtained from the database 906. In various embodiments, imputation procedures or other data manipulations/filtering can occur as part of model training or in building a model (e.g., 910-912). As discussed herein, missing data values can be filled in using a number of imputation methodologies, and examples are discussed in greater detail above. As shown, the model training at 912 is used to build multiple models. The process flow 900 illustrates construction of a pair of models, a challenger model and 914 and a champion model in 918. In other embodiments, a plurality of models can be constructed and evaluated against each other making up hosts of challenger and champion models. Process 900 illustrates the construction and evaluation of a pair of models for clarity, where the pair are evaluated to determine a better performer and the use of same in the system. According to some embodiments, a challenger model can be constructed at 914 and validated using the validation data and a champion model can be defined at 918. In other embodiments, multiple models are constructed and each is validated to determine performance metrics in terms of accuracy and/or error rate. The better performing model can be used in system deployments at 930-932 to provide the most accurate predictions and optimizations across a materials management system and/or application.

As shown, process 900 includes hyperparameter tuning at 916 to improve the operation of trained models (e.g., challenger model 914 or champion model 918). Given of plurality of models each of the respective models can be tuned to improve performance and then evaluated against existing implementation. According to one embodiment, an initial model is generated and deployed at 930 as long as the initial model meets validation requirements. In one example, the validation requirements can include a validation or error rate threshold that a model must meet before deployment. The validation data (e.g., 920) can be used to determine how a given model performs. The initial model can be referred to as a challenger model that can be deployed at 930 and further model construction can be evaluated to determine at 932 which of a challenger or a champion model should be used in subsequent operation.

Process 900 illustrates a first time deployment execution at 934 of an initial model as the challenger model. Once a model has been identified as best performer or a selection of an initial model occurred, it can be deployed as a web service compliant with the REST model. In various examples, the web service can be deployed as part of an MMS application and/or system and used to predict an optimal scheduling at 940. The optimal scheduling at 940 can be determined from a prediction of optimal renewable gas output based on having a respective set of feedstock inputs. As part of the optimization, the system resources (e.g., including any greenhouse gas emissions) utilized to deliver the feedstock inputs from respective locations to respective digesters are also accounted for in the optimization. According to some examples, given an optimal renewable gas production the required inputs (e.g. feedstock sources) can be derived to ensure the optimal production. In still other examples, once required inputs are established the resources required to provide those inputs can be determined. For example, a route from a feedstock source to a digester can be established by calculation or lookup. In one example, the distance traveled as well as traffic considerations can be used (post lookup) to determine resource utilization, and more specifically what greenhouse gas emissions are imposed in the hauling and distribution of the feedstock sources to a given digester in order to produce and optimize renewable gas output. According to one embodiment, hauler parameters (e.g., vehicles used, distance travelled, emissions produced over distances) are known or computable values. Thus, resource utilization can be determined historically and can used in optimizing renewable gas production (including embodiments that minimize resource expenditure). Various embodiments are tailored to optimize not only renewable gas output but to optimize (e.g., reduce) the resulting greenhouse gas emissions produced during operation of the system.

As shown process 900 includes a feedback loop for shown at 950-960 where operational data is captured and stored as part is historical materials management insight data. As more data is collected over time, the training data at 908 and validation data at 920 can be updated and new model training can be executed at 910, 912 to develop additional challenger and/or champion models at 914 and 918, among other examples. This cycle 950-960 is repeated over time to improve the accuracy and/or error rate associated with trained models. Any improvement in model accuracy can result in a new deployment of a new machine learning model and yield improvements in predicted scheduling and renewable gas output optimization.

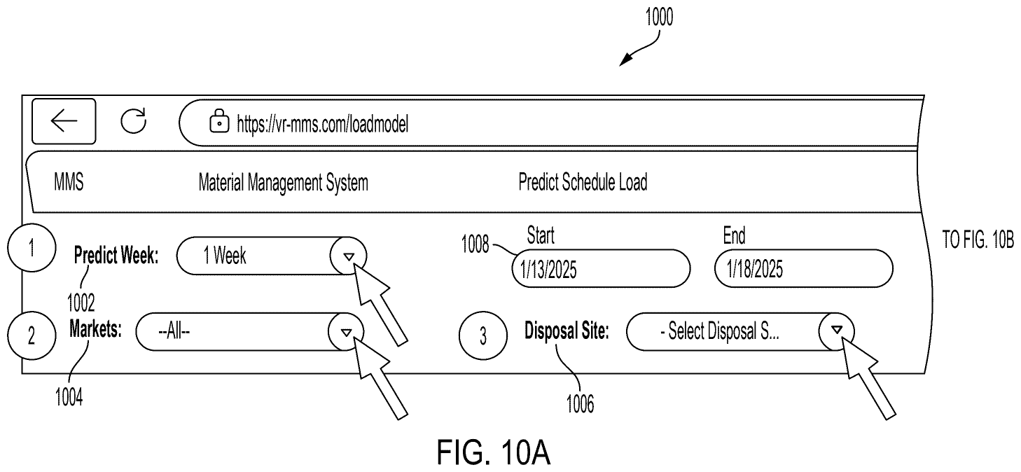

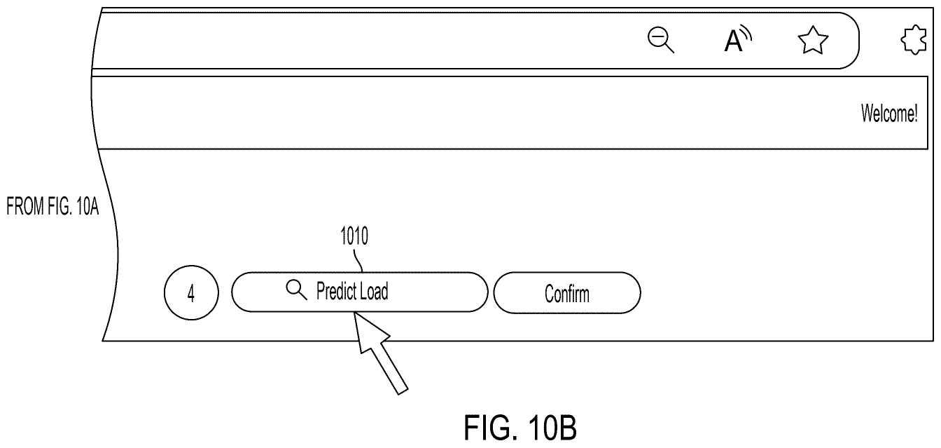

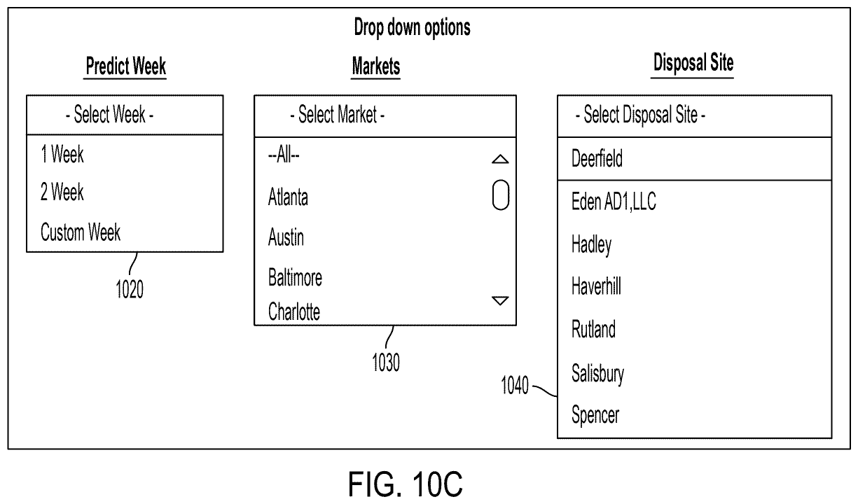

Show in in FIG. 10A is an example user interface 1000 that can be displayed by the system. According to one embodiment, users can access the user interface 1000 to trigger machine learning functions on the system. For example, users can access the machine learning functionality to predict a schedule that optimizes renewable gas production. The users can establish a time period for the prediction at 1002 via the display drop-down. Users can also specify the start of the time period at 1008 by inputting either a start or end date and a respective window. In various examples, users can specify custom prediction ranges by inputting start and end dates (e.g. at 1008). Users can also specify a market or location for which a schedule should be generated, for example, at 1004. The user interface also includes options for selecting or defining a disposal site at 1006 associated with a schedule to be generated. Shown in FIG. 10B is the selectable display 1010 that is configured to trigger execution of the prediction according to the parameters defined in the user interface (e.g., 1002-1008).

FIG. 10C shows example options that can be displayed as part of the drop-down selections made or displayed to users interacting with the interface shown in FIGS. 10A-B. For example, a “Predict Week” drop-down display can include selections for one week, two weeks, or custom week ranges (e.g., 1020) as well as options for defining a custom date range. Upon selection of markets at 1004 a drop-down can be displayed with system defined markets, for example, as shown in 1030. In response to selection of disposal site at 1006 a drop-down display can be configured to enable selection of one or more disposal sites in the drop-down menu, for example, as shown at 1040.

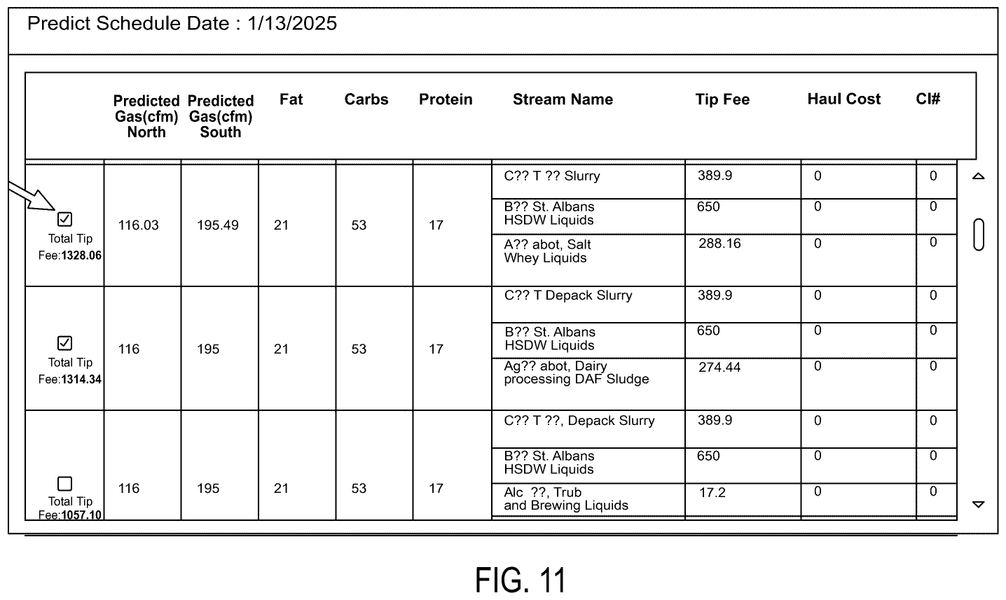

Shown in FIG. 11 is an example prediction schedule and associated time frame. In the example, the first column reflects an optimized predicted renewable gas production for a first digester and a second digester (e.g., “North,” and “South”). The display includes a prediction regarding inputs required for the specific predicted and optimized output. As part of generating the prediction, the machine learning models can identify optimal sourcing to meet the demand required to produce the predicted renewable gas output. The models can generate the optimal source based on available defined streams and/or locations of respective streams, among other options.

According to some embodiments, associated resource utilization can also be optimized as part of the machine learning prediction as discussed herein. As shown in the display, this can be represented by a tip fee associated with respective streams and/or all costs associated with the same. In the example shown there is no associated haul cost because the respective streams are self-haulers or in other words will deliver the feedstock sources to the digesters without accounting as a separate expense. As discussed above, the routing and volume of feedstock includes specific transportation over a known or derivable route. The system can utilize external mapping services to determine a route and total travel for respective hauler and derive a greenhouse gas emission value associated with the respective delivery. According to some embodiments, the system is configured not only to optimize renewable gas production but also to minimize greenhouse gas emissions as part of operation, much of which can be attributed to transportation resources. The derived values for respective routes and/or timing of transport can be used in predicting an optimal schedule.

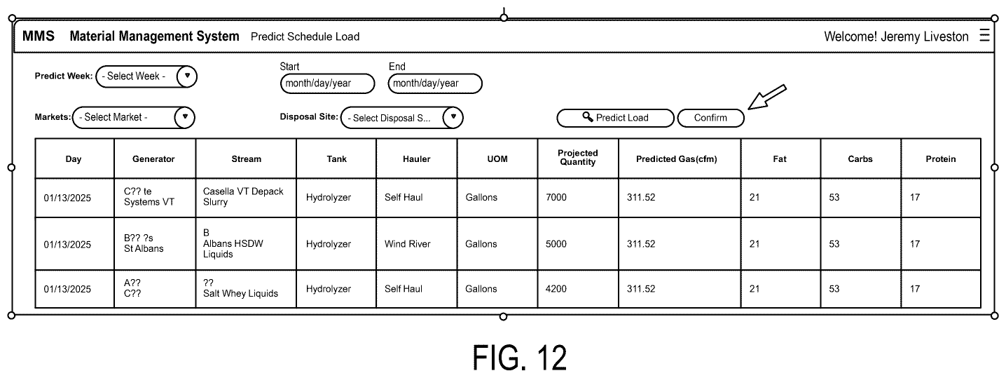

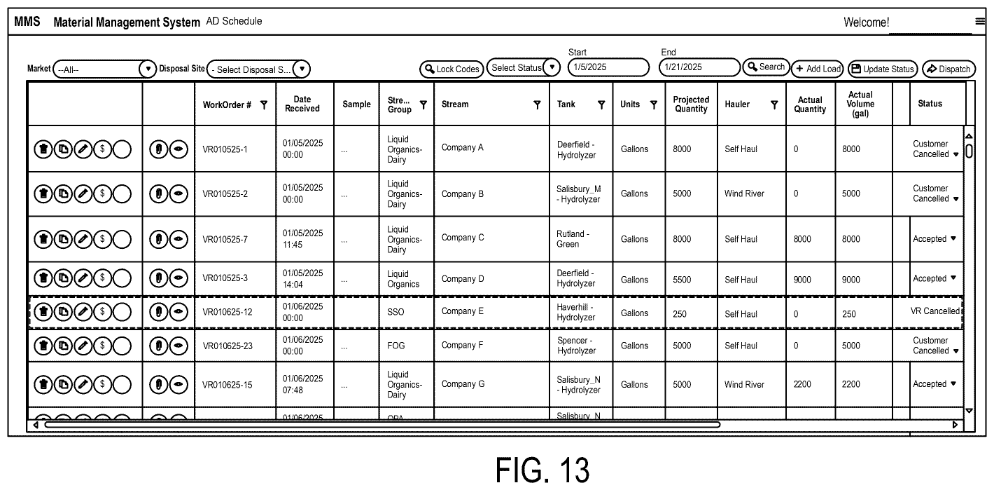

FIG. 12 shows an example user interface for displaying predicted load and associated schedule so that a user can confirm a proposed schedule/load. FIG. 13 shows an example user interface for accessing confirmed loads in respective schedules. The user interface shown in FIG. 13 enables end users to access or update status as potential schedules are confirmed, rejected, and/or modified, among other options. In various embodiments, the system is configured to display additional user interfaces that enable users to add or configured sites (e.g., digesters, digester operational characteristics, etc.), and or configured feedstock sources and associated details, among other options.

### Example Platform Implementation

Various embodiments leverage machine learning predictions to provide a renewable energy production platform housing critical information across the participants in the production stream, managing and optimizing across industry segments to develop the various interdependency into single-source of the truth database. Various examples capture and optimize on data input that cover: feedstock sales-all suppliers info anywhere in country; optimizing for distance, costs, feedstock, strength; logistics-haulers, pricing, distance, greenhouse gas emitted; marketingcovering farms—all production data; competitors—database for all participants in the production stream—landfills, incinerators, wastewater, composting, including pricing information to optimize utilization of resources; development info; permitting, zoning information; pipelines, grid information (e.g., improving accuracy of resource utilization optimizations); other local/regional development assumptions; construction/capex information—including engineering, firms, pricing, etc.

In some examples, the platform is configured to manage and optimize logistics, loads, operations, biology (e.g., digester operation) and include billing/invoicing/reporting that is applicable to any site for renewable energy production. When managed by the platform any site is configured to follow a unified management system (processes, controls, governance, etc.) that can be automated and optimized via machine learning predictions, validated under execution, and fine-tuned over time with newly capture operation data. Cloud based systems provide distributed access and opportunities for further system based efficiency, even in scaling to new sites and integrating new feedstock sources.

In further example, the platform is configured to resolve issues with data that is currently housed inconsistently and in different locations by each segment (excel, salesforce, etc.), reduce time in compiling information from multiple data sources, provide a prospecting tool—where access to a standardized database allows for significantly more efficient analysis and access to information (e.g., improving model training data), even predictions on any participant in the production chain; targeting areas for future organics/feedstock projects and development; where optimization and validation data enable feasibility review; integration of a real-time mapping tool used for initial modelling feasibility and project opportunity assessment—any of which can be used to lead to shorter siting cycles as well as reducing time to change operational parameters to resolve inefficiencies or leverage efficiencies. Hosting a distributed platform provides new opportunity to leverage technology/AI, building more robust data repositories for further training and validation, improving over conventional approaches and known systems.

### Numbered Embodiments

1. A processing system comprising:
   at least one processor operatively connected to a memory, the at least one processor configured to: access operational parameters for digester/hydrolyzer (“D/H”) component, the D/H component configured to accept a feedstock input and generate a processed output; monitor the processed output produced by the D/H component; generate candidate operational parameters, including distribution and allocation of feedstock sources based on emulation of one or more of: operation of the D/H component, the processed output produced, or the feedstock input; and control operation of the D/H component to execute to a minimum level of processed output defined by the candidate parameters.
2. A system for managing conversion of feedstock sources into renewable energy, the system comprising: at least one processor operatively connected to a memory, the at least one processor when executing configured to: train a first machine learning model on a plurality of parameters defining inputs to at least one digester and a gas output produced by a respective at least one digester; predict on gas output produced by the respective at least one digester in response to receiving definition of inputs supplied to the respective at least one digester; and trigger execution of the first machine learning model to generate a prediction on gas output based on a defined time period specified in the user interface, a specified digester, and available input sources.
3. The system of any preceding embodiment, wherein the emulation includes emulating physical properties of the processed output produced, physical properties of the feedstock input, operational parameters associated with the D/H component.
4. The system of any preceding embodiment, wherein the emulation includes executing a first machine learning model configured to predict material need for one or more D/H components.
5. The system of any preceding embodiment, wherein the first machine learning model is trained on material consumption and processed output data, and once trained the first machine learning model is configured to predict an anticipated material need for one or more D/H components having one or more locations.
6. The system of any preceding embodiment, wherein the emulation includes executing a second machine learning model configured to predict an optimal distribution schedule for allocation of feedstock sources to one or more locations.
7. The system of any preceding embodiment, wherein the second machine learning model is trained on material need and resource utilization for distribution, and once trained the second machine learning model is configured to predict the optimal distribution schedule upon input of a predicted material need for one or more D/H components having one or more locations.
8. The system of any preceding embodiment, further comprising a set of sensors configured to monitor internal operating parameters of the D/H component.
9. The system of any preceding embodiment, wherein the system is configured to update training of one or more of the first or second machine learning models with data returned from the set of sensors.
10. The system of any preceding embodiment, wherein the system is configured to correlate external parameters with data from the set of sensors.
11. The system of any preceding embodiment, wherein the system is configured to update training of one or more of the first or second machine learning models with data returned from the set of sensors and the external parameters.
12. The system of any preceding embodiment, wherein the at least one processor is configured to define a transport schedule meeting the prediction requirements generated for the specified digester and the available input sources.
13. The system of any preceding embodiment, wherein the at least one processor is configured to: generate an initial schedule of feedstock utilization and transportation for optimized renewable energy production; and communicate the initial schedule to a plurality of participants.
14. The system of any preceding embodiment, wherein the at least one processor is configured to: require acknowledgment or acceptance by the plurality of participants for respective contributions to the initial schedule.
15. The system of any preceding embodiment, wherein the at least one processor is configured to: regenerate the initial schedule of feedstock utilization and transportation, responsive to a failed acknowledgement or rejection by any one of the plurality of participants.
16. The system of any preceding embodiment, wherein the at least one processor is configured to: limit regeneration to contributions associated with rejection or failed acknowledgement.
17. The system of any preceding embodiment, wherein the at least one processor is configured to: enable definition of an emission target for a respective gas output, and optimize gas production prediction for inputs required and transportation to meet the emissions target.
18. The system of any preceding embodiment, wherein the at least one processor is configured to access or accept definition of a feedstock source profile, including definition of location, make-up of stream, and quality of stream.
19. The system of any preceding embodiment, wherein the at least one processor is configured to access or accept definition of a digester profile, including definition of a location, input requirements, and any operating parameters.
20. The system of any preceding embodiment, wherein the at least one processor is configured to access or accept definition of a disposal site profile, including definition of a location, resource requirements, and any operating parameters.
21. The system of any preceding embodiment, wherein the at least one processor is configured to: train a second machine learning model on resource need for a gas output and routing of the needed resources to meet need; and generate an optimized schedule output from the second ML model based on a resource need for a gas output, a specified one or more digester locations, specified one or more source locations over an input time period.
22. The system of any preceding embodiment, wherein the second ML model is further trained on disposal requirements for the needed resources and scheduling for any disposal.
23. The system of any preceding embodiment, wherein the at least one processor is configured to generate a schedule of feedstock utilization and associated transportation based on the gas output prediction; and trigger execution of the schedule of feedstock utilization and the associated transportation.
24. A computer implement method for executing the system of any embodiment 1-23.
   Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.
   All definitions, as defined and used herein, should be understood to control over dictionary definitions, and/or ordinary meanings of the defined terms. As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

Use of ordinal terms such as “first,” “second,” “third,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term).

The phrasecology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the techniques described herein in detail, various modifications, and improvements will readily occur to those skilled in the art. Such modifications and improvements are intended to be within the spirit and scope of the disclosure. Accordingly, the foregoing description is by way of example only, and is not intended as limiting. The techniques are limited only as defined by the following claims and the equivalents thereto.

What is claimed is:

1. A system for managing conversion of feedstock sources into renewable energy, the system comprising:
at least one processor operatively connected to a memory, the at least one processor when executing configured to:
train a first machine learning model on a plurality of parameters defining inputs to at least one digester and a gas output produced by a respective at least one digester;
predict on gas output produced by the respective at least one digester in response to receiving definition of inputs supplied to the respective at least one digester; and
trigger execution of the first machine learning model to generate a prediction on gas output based on a defined time period specified in the user interface, a specified digester, and available input sources.

2. The system of claim 1, wherein the at least one processor is configured to:
generate an initial schedule of feedstock utilization and transportation for optimized renewable energy production; and
communicate the initial schedule to a plurality of participants.

3. The system of claim 2, wherein the at least one processor is configured to:
require acknowledgment or acceptance by the plurality of participants for respective contributions to the initial schedule.

4. The system of claim 3, wherein the at least one processor is configured to:
regenerate the initial schedule of feedstock utilization and transportation, responsive to a failed acknowledgement or rejection by any one of the plurality of participants.

5. The system of claim 3, wherein the at least one processor is configured to:
limit regeneration to contributions associated with rejection or failed acknowledgement.

6. The system of claim 1, wherein the at least one processor is configured to:
enable definition of an emission target for a respective gas output, and
optimize gas production prediction for inputs required and transportation to meet the emissions target.

7. The system of claim 1, wherein the at least one processor is configured to access or accept definition of a feedstock source profile, including definition of location, make-up of stream, and quality of stream.

8. The system of claim 1, wherein the at least one processor is configured to access or accept definition of a digester profile, including definition of a location, input requirements, and any operating parameters.

9. The system of claim 1, wherein the at least one processor is configured to access or accept definition of a disposal site profile, including definition of a location, resource requirements, and any operating parameters.

10. The system of claim 1, wherein the at least one processor is configured to:
train a second machine learning model on resource need for a gas output and routing of the needed resources to meet need; and
generate an optimized schedule output from the second ML model based on a resource need for a gas output, a specified one or more digester locations, specified one or more source locations over an input time period.

11. The system of claim 10, wherein the second ML model is further trained on disposal requirements for the needed resources and scheduling for any disposal.

12. The system of claim 1, wherein the at least one processor is configured to
generate a schedule of feedstock utilization and associated transportation based on the gas output prediction; and
trigger execution of the schedule of feedstock utilization and the associated transportation.

13. A computer implemented method for managing conversion of feedstock sources into renewable energy, the method comprising:
training, by at least one processor, a first machine learning model on a plurality of parameters defining inputs to at least one digester and a gas output produced by a respective at least one digester;
predicting, by the at least one processor, gas output produced by the respective at least one digester in response to receiving definition of inputs supplied to the respective at least one digester; and
triggering, by the at least one processor, execution of the first machine learning model to generate a prediction based on a defined time period specified in the user interface, a specified digester, and available input sources.

14. The method of claim 13, wherein the method comprises:
generating an initial schedule of feedstock utilization and transportation for optimized renewable energy production; and
communicating the initial schedule to a plurality of participants.

15. The method of claim 14, wherein the method comprises requiring acknowledgment or acceptance by the plurality of participants for respective contributions to the initial schedule.

16. The method of claim 15, wherein the method comprises regenerating the initial schedule of feedstock utilization and transportation, responsive to a failed acknowledgement or rejection by any one of the plurality of participants.

17. The method of claim 16, wherein the method comprises limiting regeneration to contributions associated with rejection or failed acknowledgement.

18. The method of claim 13, wherein the method comprises enabling definition of an emission target for a respective gas output, and optimize gas production prediction for inputs required and transportation to meet the emissions target.

19. The method of claim 13, wherein the method comprises accessing or accepting definition of a feedstock source profile, including definition of location, make-up of stream, and quality of stream.

20. The method of claim 13, wherein the method comprises accessing or accepting definition of a digester profile, including definition of a location, input requirements, and any operating parameters.

21. The method of claim 13, wherein the method comprises accessing or accepting definition of a disposal site profile, including definition of a location, resource requirements, and any operating parameters.

22. The method of claim 13, wherein the method comprises:
training a second machine learning model on resource need for a gas output and routing of the needed resources to meet need; and
generate an optimized schedule output from the second ML model based on a resource need for a gas output, a specified one or more digester locations, specified one or more source locations over an input time period.

23. The method of claim 22, wherein the second ML model is further trained on disposal requirements for the needed resources and scheduling for any disposal, and the at least one processor is optionally configured to trigger execution of the optimized schedule.
